(19) United States
(12) Patent Application Publication
(10) Pub. No.: US 2006/0116834 A1
(43) Pub. Date: Jun. 1, 2006

(54) Test method and test apparatus for digital-analog converter

(75) Inventor: Shigeki Orisaka, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ADVANTEST CORPORATION

(21) Appl. No.: 11/045,493

(22) Filed: Jan. 31, 2005

(30) Foreign Application Priority Data
Dec. 1, 2004 (JP) 2004-348959

(51) Int. Cl. G01R 23/00

(52) U.S. Cl. 702/75

(57) ABSTRACT

A cyclic pattern data is input into a digital-analog (DA) converter that converts predetermined digital data into analog data. The cyclic pattern data has a symmetrical waveform when output from the DA converter. Even-numbered high harmonic components 2f₀, 4f₀ with respect to a fundamental frequency f₀ of the cyclic pattern data are observed. When there are no even-numbered high harmonic components 2f₀, 4f₀, the DA converter is determined to operate well.

### CROSS-REFERENCE TO RELATED APPLICATIONS

This application is based upon and claims the benefit of priority from Japanese Patent Application No. 2004-348959, filed Dec. 1, 2004, the entire contents of which are incorporated herein by reference.

### BACKGROUND OF THE INVENTION

1. Field of the Invention

The present invention relates to a test method and a test apparatus for a digital-analog (DA) converter and a DA converter itself which allow simple and easy implementation of accurate operation test for the DA converter, and in particular to a test method and a test apparatus for a DA converter that is capable of high-speed operation, and such a DA converter.

2. Description of the Related Art

A DA converter is a circuit that converts multi-level digital data into analog data. As shown in FIG. 12, conventionally, when an operation test is performed on a converting operation of the DA converter, a pattern generator 101 generates a test pattern and a clock to be supplied to a DA converter 104 via a cable 102 and a probe 103 as inputs, and the DA converter 104 outputs analog data which is observed with an observation device 105 such as an oscilloscope to check the operation of the DA converter 104 (see, for example, Japanese Patent Laid-Open No. 2003-133955).

### SUMMARY OF THE INVENTION

With the increase in operation speed of the DA converter, however, a pattern generator which can accommodate the increase in operation speed becomes necessary, and at the same time, a cable and probe become necessary which can supply as inputs to the DA converter a high-speed test pattern and a high-speed clock, which are output from the pattern generator, without degradation in waveform and with a sufficient input level. When such pattern generator, cable and probe are not employed, a sufficient operation test cannot be performed on the DA converter that operates at high-speed.

On the other hand, when the operation test for the DA converter is performed with a pattern generator that accommodates the high-speed operation, a cable and probe that transmit the high-speed digital data without degradation in waveform quality, the device scale becomes large, and the wiring for the operation test become time consuming, and costly.

In addition, since the operation test of the DA converter is generally performed through the observation of output analog waveform with an oscilloscope or the like, the loyalty of output of analog output waveform with digital input cannot be tested with high accuracy. In particular, when the DA converter operates at high-speed, a highly accurate test is difficult because of the limitation in accuracy of the observation device itself, such as an oscilloscope.

An object of the present invention is to at least solve the problems as described above.

According to one aspect of the present invention, a test method for a DA converter includes inputting cyclic pattern data which has a symmetrical waveform when output from a DA converter into the DA converter, that converts predetermined digital data into analog data, and observing an even-numbered high harmonic component with respect to a fundamental frequency of the cyclic pattern data.

According to another aspect of the present invention, a test method for a DA converter includes inputting a cyclic pattern data which has a symmetrical waveform when output from the DA converter instead of a predetermined digital data into the DA converter, that converts the predetermined digital data into analog data, and observing an even-numbered high harmonic component with respect to a fundamental frequency of the cyclic pattern data.

According to another aspect of the present invention, in a test apparatus for a DA converter, a cyclic pattern data which has a symmetrical output waveform when output from a DA converter that converts predetermined digital data into analog data is generated and supplied to the DA converter.

According to another aspect of the present invention, a test apparatus for a DA converter includes: a pattern generator that generates a test pattern according to an input of a test signal; and a selector that switches an output to a DA converter side that converts received predetermined digital data into analog data to an output of the test pattern to the DA converter side according to the input of the test signal.

### BRIEF DESCRIPTION OF THE DRAWINGS

FIG. 1 is a diagram of an outline of a test method of a DA converter according to a first embodiment;

FIG. 2 is a block diagram of a detailed structure of a data selector circuit that realizes the test method of the DA converter shown in FIG. 1;

FIG. 3 is a block diagram of a structure of the DA converter incorporating the data selector circuit shown in FIG. 2;

FIG. 4 is a block diagram of a structure of a data selector circuit according to a second embodiment;

FIG. 5 is a block diagram of a structure of a DA converter incorporating the data selector circuit shown in FIG. 4;

FIG. 6 is a timing chart of a test pattern generated in the DA converter shown in FIG. 5;

FIG. 7 is a block diagram of a structure of a data selector circuit which is a modification of the second embodiment according to the present invention;

FIG. 8 is a diagram of an output waveform of analog data in a test mode of the DA converter shown in FIG. 7;

FIG. 9 is a block diagram of a structure of a DA converter according to a third embodiment of the present invention;

FIG. 10 is a waveform diagram in a normal mode and a test mode of the DA converter shown in FIG. 9 where a clock frequency is changed between the normal mode and the test mode;

FIG. 11 is a block diagram of a structure of a DA converter according to a fourth embodiment of the present invention; and

FIG. 12 is a diagram of a system structure at an operation test for a conventional DA converter.

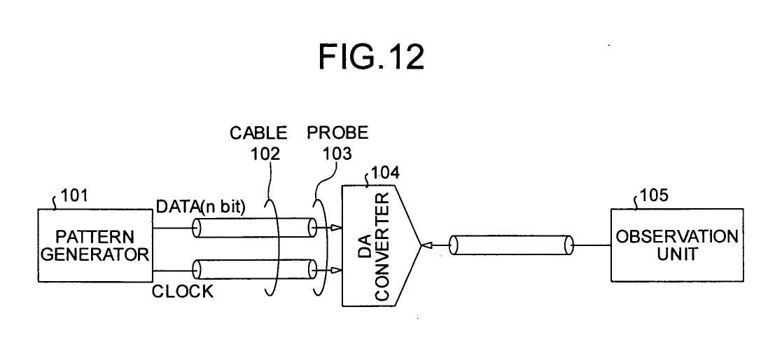

### DETAILED DESCRIPTION OF THE PREFERRED EMBODIMENTS

A test method and a test apparatus for a DA converter and the DA converter will be described herein below according to exemplary embodiments of the present invention.

### First Embodiment

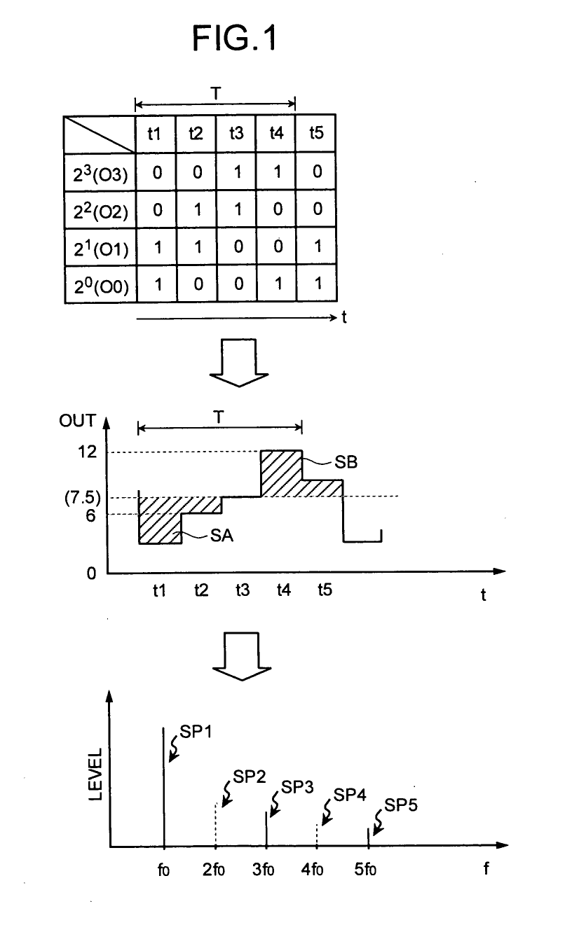

FIG. 1 shows a general concept of a test method for a DA converter according to a first embodiment of the present invention. In the test method for the DA converter shown in FIG. 1, when the DA converter (not shown) is to convert 4-bit digital data into analog data, the DA converter (not shown) first receives as an input cyclic data which circulates on one-bit basis as shown in an upper column of FIG. 1. In the upper column of FIG. 1, cyclic data are series of data “0011”, “0110”, “1100”, “1001”, “0011”, and the like.

The DA converter (not shown), on receiving the cyclic data, converts the cyclic data into analog data shown in a middle column of FIG. 1 to output. Here, the waveform of analog data is symmetrical with reference to analog value “7.5”. In other words, a lower area SA and an upper area SB are equal with analog value “7.5” as a reference value as shown in FIG. 1.

When digital data to be input to the DA converter (not shown) is cyclic data with the symmetrical waveform as mentioned above, the DA converter outputs, in addition to a fundamental wave SP1 (frequency f₀) of analog data waveform, a high harmonics SP2 to SP5 (2f₀to 5f₀). In the drawing, high harmonics higher than sixth order are not shown.

When the DA converter (not shown) is operating normally, the high harmonics SP2 and SP4 of the even orders do not appear. The normal operation of the DA converter means here that the voltages at respective levels are properly operating at the time of DA conversion. Hence, the operation test of the DA converter (not shown) can be conducted through an input of cyclic data with symmetrical waveform as mentioned above into the DA converter (not shown), observation of the output waveform with an observation device such as a spectral analyzer, and checking the presence/absence or the level of the even-numbered high harmonics SP2 and SP4.

Then, not the time waveform but the even-numbered high harmonic spectral value is observed for the measurement of the level thereof, whereby the test can be readily conducted in a simple manner with a high accuracy. In addition, even when the DA converter (not shown) operates at a high-speed, since only the even-numbered high harmonic spectral value is checked and measured in a quantified manner as described above, highly accurate test can be securely conducted.

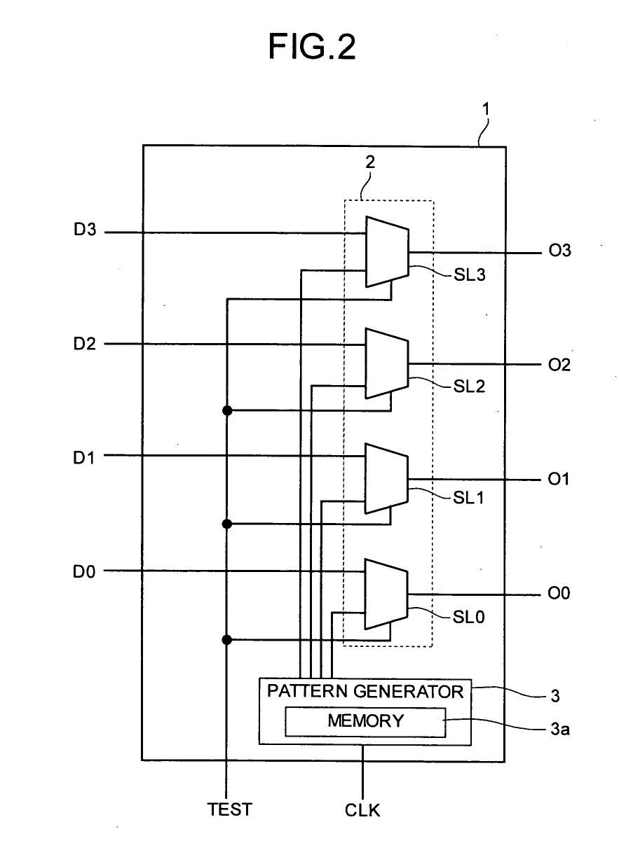

FIG. 2 is a diagram of a structure of a test apparatus for the DA converter that realizes the above mentioned test method for the DA converter. A data selector circuit 1 shown in FIG. 2 functions as a test apparatus for the DA converter (not shown) that converts 4-bit digital data into analog data, and is arranged at a previous stage to the DA converter.

The data selector circuit 1 includes a selector 2 and a pattern generator 3. The selector 2 receives 4-bit digital data D0 to D3 as inputs which are supplied respectively to selector circuits SL0 to SL3. The pattern generator 3 includes a memory 3a, on which test patterns, i.e., cyclic data with a symmetrical waveform mentioned above, are stored, and the test patterns are supplied to the corresponding selector circuits SL0 to SL3. Each of the selector circuits SL0-SL3 receives a test signal TEST as an input. When the test signal TEST is at a low level, the data selector circuit 1 is switched over to a normal operation mode (normal mode) to output the received digital data D0 to D3 as they are to the DA converter (not shown) as output data O0-O3, whereas when the test signal TEST is at a high level, the data selector circuit 1 is switched over to a test mode to output test patterns supplied from the pattern generator 3 to the DA converter (not shown) as the output data O0-O3. The pattern generator 3 operates according to a clock signal CLK as received.

The data selector circuit 1, which serves as a test apparatus for the DA converter, is capable of readily and flexibly switching over the normal mode and the test mode through the switching over between the digital data D0-D3 and the test patterns.

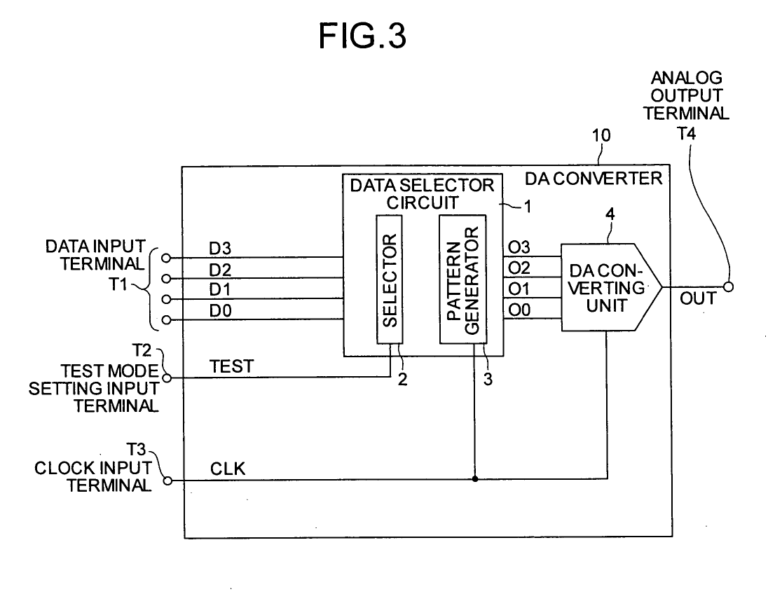

FIG. 3 is a diagram of a structure of a DA converter including the data selector circuit 1 mentioned above and a DA converting unit 4 which functions as a DA converter. Thus, the DA converter 10 realizes the DA converting unit 4 and the data selector circuit 1 in one apparatus.

As shown in FIG. 3, the DA converter 10 includes a data input terminal T1 to receive 4-bit digital data D0 to D3 to be DA converted, a test mode setting input terminal T2 to receive the test signal TEST, a clock input terminal T3 to receive the clock signal CLK, and the data selector circuit 1 and the DA converting unit 4 inside. In addition, the DA converter 10 includes an analog output terminal T4 to externally output analog data OUT as a result of conversion by the DA converting unit 4.

As described above, the data selector circuit 1 receives digital data D0-D3 at the data input terminal T1, the test signal TEST at the test mode setting input terminal T2, and the clock signal CLK at the clock input terminal T3. The clock signal CLK is also supplied to the DA converting unit 4 which receives digital data O0 to O3 output from the data selector circuit 1. The DA converting unit 4 converts digital data O0 to O3 into analog data OUT according to the clock signal CLK as an operation clock, and output OUT via the analog output terminal T4.

Though the DA converter 10 mentioned above does not need to be formed from one chip, it is preferable to form the DA converter 10 as one chip having the data input terminal T1, the test mode setting input terminal T2, the clock input terminal T3, and the analog output terminal T4. When the device is formed as one chip, wiring-induced degradation in waveform and loss would be eliminated and the wiring for high-speed operation test can readily be formed.

The DA converter 10 is realized as a chip which is switched to the test mode at the time of delivery or maintenance for the test, and otherwise functions as a normal DA converter, and further, is capable of eliminating a waveform degradation and loss caused by the wiring at the time of test and of realizing a highly accurate test.

Though, in the first embodiment as described above, digital data D0 to D3 are 4-bit multi-level data, this is not a limiting example and arbitrary number of parallel bits can be employed, for example, 8-bit parallel data, 16-bit parallel data, or the like.

### Second Embodiment

Next, a second embodiment of the present invention will be described. In the first embodiment as described above, the pattern generator 3 generates the test patterns. In the second embodiment, however, the test patterns are generated with the use of received digital data D0-D3.

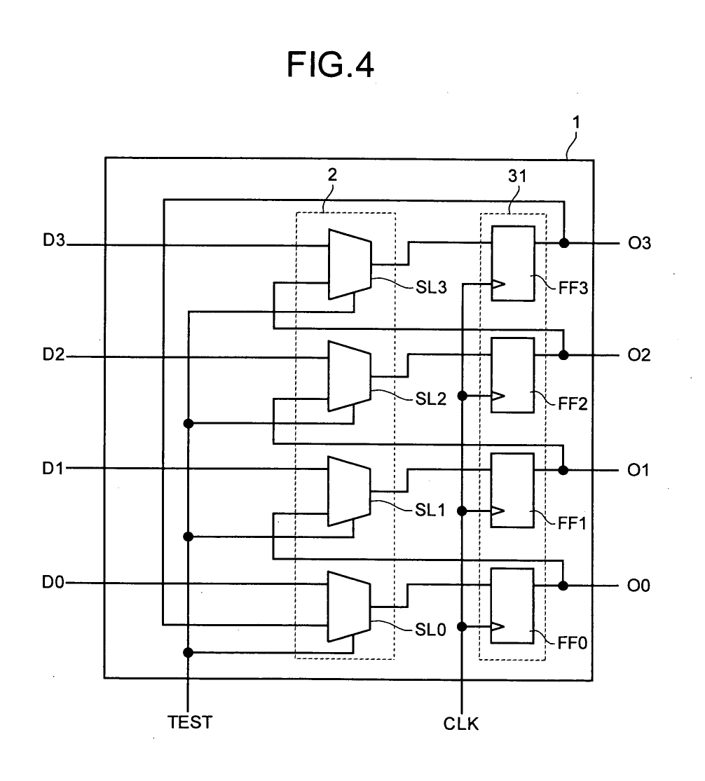

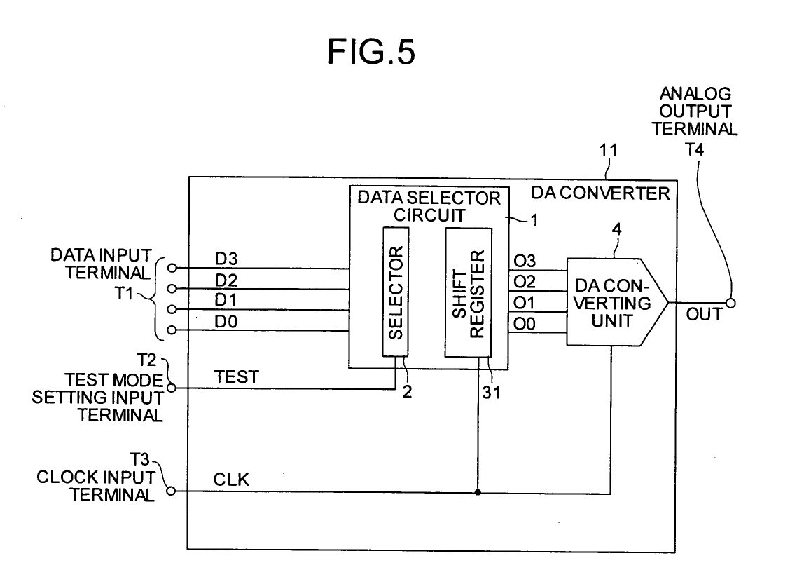

FIG. 4 is a diagram of a detailed structure of a data selector circuit 1 according to the second embodiment of the present invention. FIG. 5 is a diagram of an overall structure of a DA converter 11 mounting the data selector circuit 2. In FIGS. 4 and 5, the data selector circuit 1 includes a shift register 31 having stages corresponding to the bit number instead of the pattern generator 3. The shift register 31 is arranged, for example, between the selector 2 and the DA converting unit 4, and includes four flip flop circuits FF0 to FF3. The selector circuits SL0 to SL3 receive digital data D0, D1, D2, D3 and output data O3, O0, O1, O2 respectively supplied from the flip flop circuit FF3, FF0, FF1, FF2, respectively, and either the digital data D0 to D3 or the output data O3 to O2 selected according to the received test signal TEST are supplied to the flip flop circuits FF0-FF3. The flip flop circuits FF0-FF3 latch the data supplied from the selector circuits SL0 to SL3, respectively to supply as the output data O0 to O3 to the DA converting unit 4.

Here, the flip flop circuits FF0 to FF3, when the test signal TEST is at a low level, after latching the received digital data D0 to D3, output the data as they are as output data O0 to O3 according to the clock signal CLK. On the other hand, the flip flop circuits FF0-FF3 latch the digital data D0 to D3 at the time the test signal TEST attains a high level, form a shift register that circulates and shifts latched bit value according to the clock signal CLK, and the flip flop circuits FF0-FF3 output the output data O0 to O3 as parallel data according to the clock signal CLK.

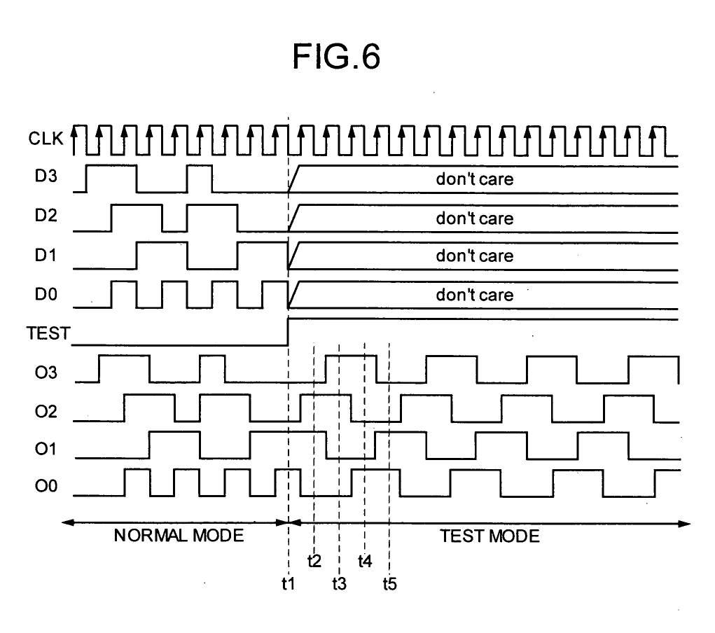

Specifically, as shown in FIG. 6, parallel data DT0, DT1, DT2, DT3, i.e., digital data D0, D1, D2, D3 respectively latched by the flip flop circuits FF0, FF1, FF2, FF3 at a point t1 when the test signal TEST turns from a low level to a high level, are output as output data O0, O1, O2, O3, and at the same time shifted to the next flip flop circuits FF1, FF2, FF3, FF0 via the selector 2. Then at a point t2, the shifted parallel data DT3, DT0, DT1, DT2 are output as the next output data O0, O1, O2, O3 and shifted. When one particular output data among O0 to O3, output data O0, for example, is to be described, the output data O0 changes from the point t1 when the test signal TEST attains a high level from DT1, DT0, DT3, DT2, DT1, DT0, and the like, as cyclic data.

More specifically, the output data O0 to O3 are the parallel data formed by the circulation of the parallel data DT0-DT3, i.e., “1,1,0,0” latched at the point t1 is sequentially output to form a test pattern. The output data O0 to O3 as the test pattern is later converted into analog values according to the level by the DA converting unit 4 to be supplied as analog data OUT.

Since the digital data DT0 to DT3 as latched by the shift register 3 at the time of transition to the test mode is subsequently circulated to be parallel output data O0 to O3 as the test pattern in the second embodiment, a desired test pattern can be readily formed at a high-speed.

Here, though in the second embodiment as described above, the number of stages of the flip flop circuits FF0 to FF3 forming the shift register 31 is same with the number of bits of digital data D0 to D3, this is not a limiting example and the number of stages of the flip flop circuits may be larger than the number of bits of digital data D0 to D3.

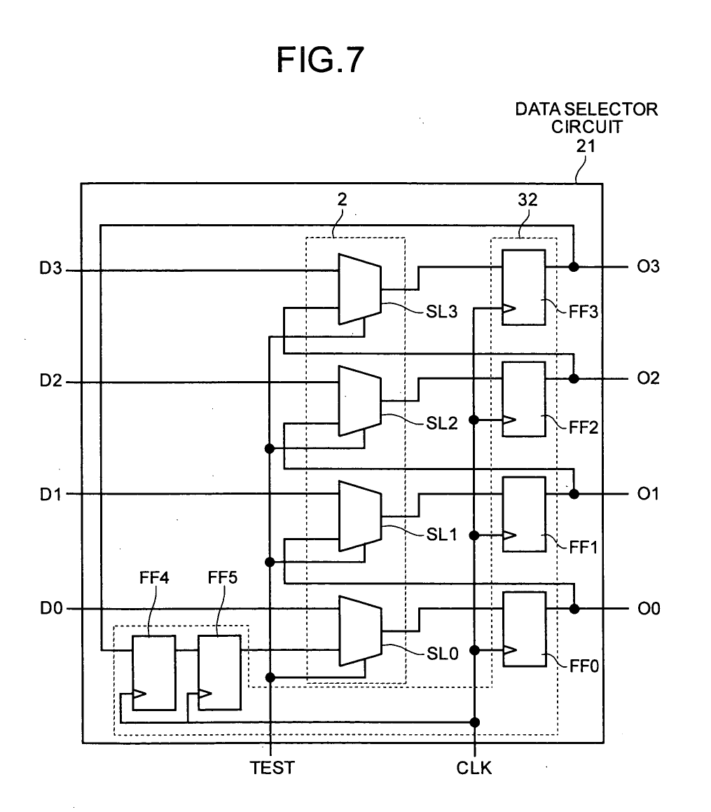

FIG. 7 is a diagram of a detailed structure of the data selector circuit of the second embodiment of the present invention. As shown in FIG. 7, a shift register 32 of the data selector circuit 32 has a structure where two stages of flip flop circuits FF4 and FF5 are connected in a previous stage of one shift register consisting of the flip flop circuits FF0 to FF3. Hence, the output data O3 of the flip flop circuit FF3 is supplied to the flip flop circuit FF4, the output data of the flip flop circuit FF5 is supplied to the selector circuit SL0, and in turn, to the flip flop circuit FF0 via the selector circuit SL0. In other points, the structure is same with the data selector circuit 1 shown in FIG. 4 and the DA converter 10 shown in FIG. 5, and the same components are denoted with the same reference characters.

Here, when the test signal TEST attains a high level, the flip flop circuits FF0 to FF3 latch digital data D0 to D3. In addition to the data latched by the flip flop circuits FF0 to FF3, initially set bits in the flip flop circuits FF4 and FF5 undergo the cyclic shift.

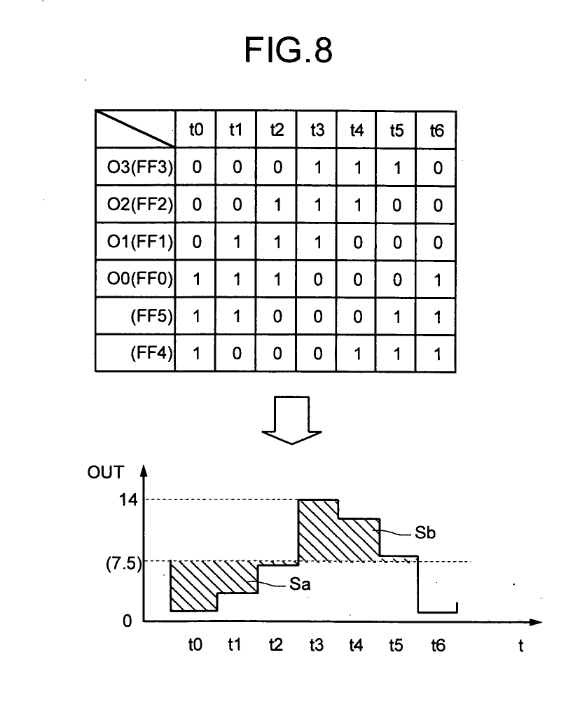

FIG. 8 shows an example of output data O0 to O3 in the test mode by the data selector circuit 21 shown in FIG. 7. As shown in FIG. 8, with the addition of the flip flop circuits FF4 and FF5, the cycle of cyclic test pattern lengthens, which enables generation of a wider variety of test patterns. In particular since the flip flop circuits FF4 and FF5 add bits, the symmetrical waveform where the areas Sa and Sb are the same can be readily generated as shown at the bottom part of FIG. 8 and the various operation tests can be readily performed for the DA converting unit 4.

Though in the modification of the second embodiment, the shift register 32 is realized as six-stage register with two stages consisting of the flip flop circuits FF4 and FF5, one stage or more than three stages of flip flop circuits may be added. In addition, the flip flop circuits FF4 and FF5 may be arranged between the flip flop circuits FF1 and FF2, for example to allow the generation of various test patterns.

Further, though in the second embodiment and the modification thereof as described above, the digital data D0 to D3 conduct the cyclic shift towards upper bit side, this is not a limiting example. However, the shift of the flip flop circuits FF0 to FF5 may not be followed by the next adjacent flip flop circuit so as to form a shift register with various shift order and to generate various test patterns. For example, some flip flop circuits may be cross-connected to each other.

### Third Embodiment

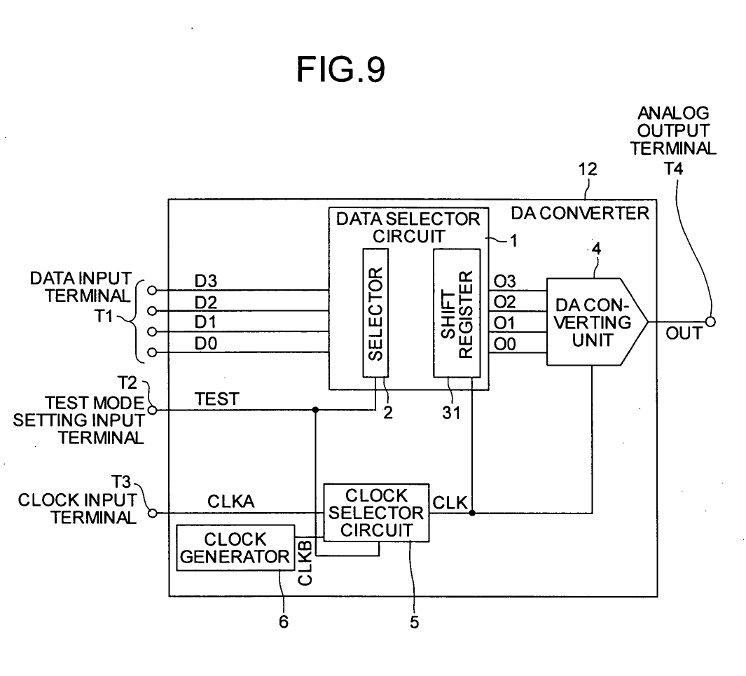

Next, a third embodiment of the present invention will be described. In the third embodiment, a clock generator is further provided in the DA converter. FIG. 9 is a diagram of an overall structure of a DA converter according to the third embodiment of the present invention. In FIG. 9, a DA converter 12 has a structure similar to the DA converter 11 shown in FIG. 5 but includes a clock selector circuit 5 and a clock generator 6 inside.

The test signal TEST is input to the data selector circuit 1 as well as to the clock selector circuit 5. The clock selector circuit 5 receives as inputs an external clock signal CLKA supplied from the clock input terminal T3 and an internal clock signal CLKB supplied from the clock generator 6 which is a free-running oscillator, selects the external clock signal when the test signal TEST attains a low level and selects the internal clock signal CLKB when the test signal TEST attains a high level, and output the selected signal as the clock signal CLK to the data selector circuit 1 and the DA converting unit 4. The clock signal CLK is employed as an operation clock for the data selector circuit 1 and the DA converting unit 4.

The DA converting unit 4 converts the output data O0-O3 as 4-bit multi-level data into analog data and output the analog data OUT from the analog output terminal T4. The DA converting unit 4 has the operation speed determined according to the clock signal CLK, operates at the clock speed of the external clock CLKA in the normal mode and at the clock speed of the internal clock CLKB in the test mode.

Here, when the test signal TEST attains a high level due to the switching over to the test mode by the clock selector circuit 5, the clock signal CLK is switched from the external clock signal CLKA to the internal clock signal CLKB.

Though the clock frequency of the internal clock signal in the test mode is set at a high level for the test of high-speed operation of the DA converting unit 4, since the internal clock signal CLKB is incorporated in the DA converter 12, the internal clock signal CLKB can be supplied to the data selector circuit 1 and the DA converting unit 4 as a sufficient clock for the high-speed operation test with little waveform degradation.

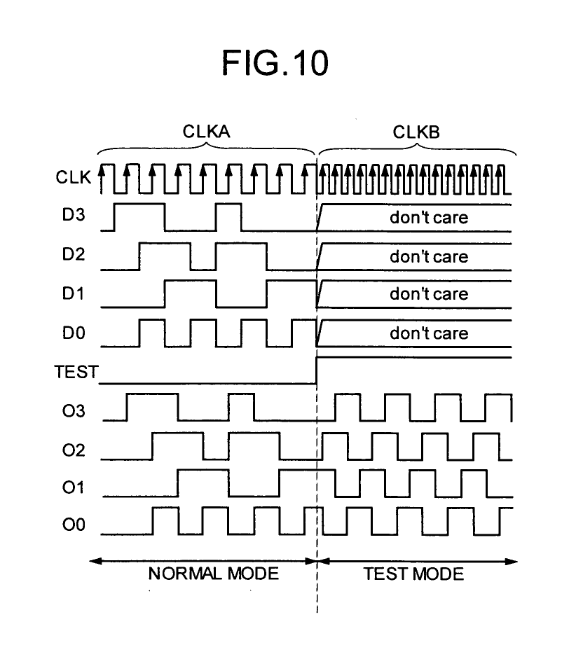

Contrarily, in the normal mode, the external clock signal CLKA is supplied to the data selector circuit 1 and the DA converting unit 4, and hence the clock frequency in the normal mode can be lowered at the operation test of the DA converting unit 4. In other words, the external clock signal CLKA, which is a low-speed clock frequency signal, can be supplied from the clock input terminal T3. As described above, when the test signal TEST attains a high level, the digital data D0 to D3 are latched and the latched parallel data DT0 to DT3 determine the test pattern. Hence, when the clock frequency of the external clock signal CLKA is lowered as shown in FIG. 10, the selection of desirable test pattern by the test signal TEST can be performed securely and stably.

Since in the third embodiment, the DA converter 12 incorporates the shift register 31 and clock generator 6 that function as the test pattern generators, signal generation can be readily performed while maintaining the high-speed feature, and the high-speed operation test of the DA converting unit 4 can be readily performed in a simple manner without the need of an expensive pattern generator, or a cable and probe.

### Fourth Embodiment

Next, a fourth embodiment of the present invention will be described. In the third embodiment described above, the clock generator 6 is described as a self-running oscillator. In the fourth embodiment, it is intended to increase the stability of the self-running oscillator.

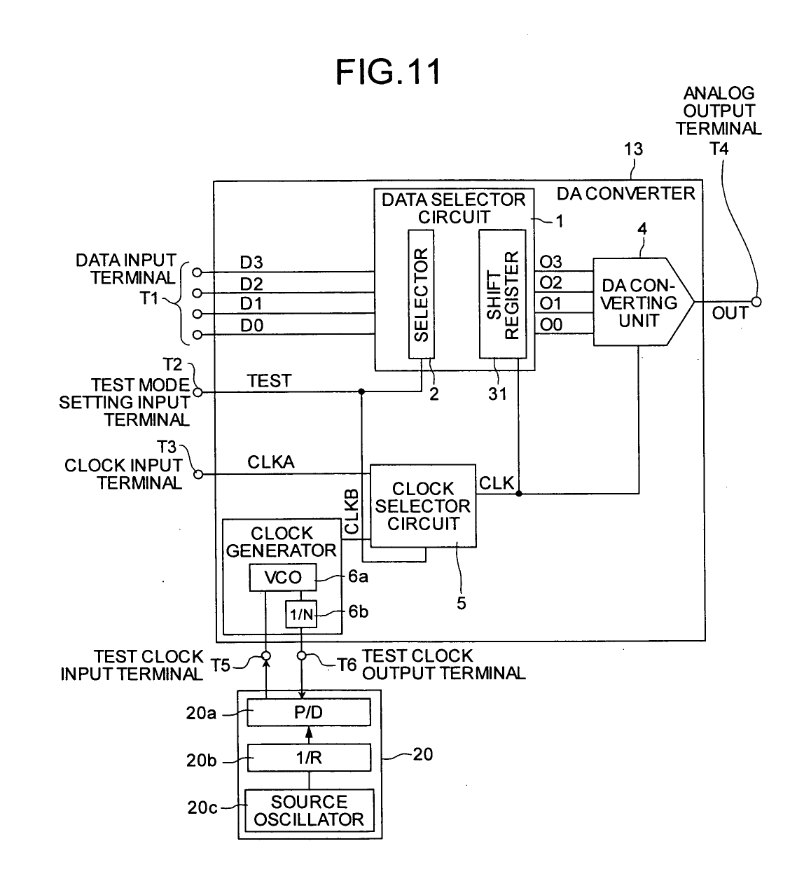

FIG. 11 is a block diagram of a structure of a DA converter according to the fourth embodiment of the present invention. In FIG. 11, the clock generator 6 of the DA converter 12 has a voltage-controlled oscillator (VCO) 6a and outputs the internal clock signal CLKB from the VCO 6a. In addition, the clock generator 6 feeds back the output of the VCO 6a via a frequency divider 6b. The DA converter 12 includes a test clock output terminal T6 to output a monitoring signal from the frequency divider 6b of the clock generator 6 and a test clock input terminal T5 to receive a control signal to voltage control the frequency of the VCO 6a. The DA converter 12 is connected to a frequency controller 20 via the test clock input terminal T5 and the test clock output terminal T6. In other points, the structure is same with FIG. 9 and the same components are denoted by the same reference characters.

The frequency controller 20 includes a source oscillator 20c realized by a quartz crystal oscillator or the like and a shift comparator 20a shift compares the signal from the source oscillator 20c via the frequency divider 20b with a signal monitored by the frequency divider 6b to voltage control the frequency of the VCO 6a. Thus, the clock frequency of the VCO 6a is stabilized, in other words, a PLL circuit is realized. Hence, the frequency controller 20 does not necessarily include the source oscillator 20c and the frequency divider 20b as far as the internal clock frequency of the clock generator 6 is stabilized.

Since in the fourth embodiment, the frequency controller 20 is provided outside to feedback control the internal clock frequency generated by the clock generator 6 via the test clock input terminal T5 and the test clock output terminal T6, the internal clock frequency can be stabilized.

Thus, according to the test method and test apparatus for the DA converter and the DA converter according to the present invention, the test is conducted so that a DA converter, which converts predetermined digital data into analog data, receives cyclic pattern data with symmetrical output waveform from the DA converter, even-numbered high harmonic components with respect to the fundamental frequency of the cyclic pattern data is observed and the DA converter is determined to operate normally when the even-numbered high harmonic components are not observed. Thus, highly accurate test for the DA converter can be readily performed in a simple manner.

Other advantages and modifications will readily be apparent to those skilled in the art. Hence, the present invention in its broad sense is not limited to the details and exemplary embodiments described herein. Various modifications can be made within the scope of the present invention defined according to the appended claims and their equivalents.

1. A test method for a DA converter, comprising:
inputting cyclic pattern data which has a symmetrical waveform output from a DA converter, into the DA converter that converts predetermined digital data into analog data; and
observing an even-numbered high harmonic component with respect to a fundamental frequency of the cyclic pattern data.

2. A test method for a DA converter, comprising:
inputting cyclic pattern data which has a symmetrical waveform output from the DA converter instead of predetermined digital data, into the DA converter that converts the predetermined digital data into analog data;
observing an even-numbered high harmonic component with respect to a fundamental frequency of the cyclic pattern data.

3. A test apparatus for a DA converter, wherein cyclic pattern data which has a symmetrical waveform output from the DA converter that converts predetermined digital data into analog data is generated to supply the cyclic pattern data to the DA converter.

4. A test apparatus for a DA converter, comprising:
a pattern generator that generates a test pattern according to an input of a test signal; and
a selector that switches an output to a DA converter side, which converts received predetermined digital data into analog data, to an output of the test pattern to the DA converter side, according to the input of the test signal.

5. The test apparatus according to claim 4, wherein the pattern generator is a shift register, wherein the shift register is arranged between the selector and the DA converter, has a plurality of flip flop circuits that latch each bit of the predetermined digital data at a time of the test signal input, and cyclic shifts and parallel outputs the latched bit data to the DA converter.

6. The test apparatus according to claim 5, wherein
the shift register includes at least one flip flop circuit connected to the plurality of flip flop circuits, and circulates each bit including a bit set in the at least one flip flop circuit.

7. The test apparatus according to claim 4, comprising:
a clock generator that generates a clock, and
a switching unit that switches an output of an external clock to a clock generated by the clock generator according to the input of the test signal, wherein
the DA converter and the pattern generator operate according to the clock in a test mode when the test signal is input.

8. The test apparatus according to claim 7, wherein the clock generator is a self-running oscillator,
the test apparatus further comprising a frequency controller that controls a frequency of the self-running oscillator through monitoring of the frequency of the self-running oscillator.

9. The test apparatus according to claim 4, wherein
a pattern data generated by the pattern generator is cyclic pattern data that has a symmetrical waveform output from the DA converter.

10. A DA converter, comprising:
a DA converting unit that converts predetermined digital data into analog data, and
the test apparatus for the DA converter, including
a pattern generator that generates a test pattern according to an input of a test signal; and
a selector that switches an output to a DA converter side, which converts received predetermined digital data into analog data, to an output of the test pattern to the DA converter side, according to the input of the test signal.

11. The DA converter according to claim 10, further comprising:
a data input terminal for the predetermined digital data;
a data output terminal for the analog data;
a test signal input terminal for the test signal; and an external clock input terminal that receives a clock to be supplied to the DA converting unit and the pattern generator.
